(19) United States
(12) Patent Application Publication
(10) Pub. No.: US 2026/0253650 A1
(43) Pub. Date: Aug. 27, 2026

(54) BOUNDARY WL OFFSET CONTROL BASED ON TEMPERATURE

(71) Applicant: Micron Technology, Inc., Boise, ID (US)

(72) Inventors: Yu-Chung Lien, San Jose, CA (US); Murong Lang, San Jose, CA (US); Zhenming Zhou, San Jose, CA (US)

(21) Appl. No.: 19/058,830

(22) Filed: Feb. 20, 2025

(51) Int. Cl. G11C 16/34; G11C 16/08; G11C 16/26

(52) U.S. Cl. CPC G11C 16/3418; G11C 16/08; G11C 16/26

(57) ABSTRACT

A system and method are provided for reading data from a memory device. The system and method receive a request to read data from a portion of a memory device and, in response to receiving the request to read the data, determine whether the portion of the memory device is available for writing data. The system and method retrieve a read offset value based on a temperature associated with the portion of the memory device in response to determining whether the portion of the memory device is available for writing data and read the data from the portion of the memory device based on the retrieved read offset value.

### TECHNICAL FIELD

This disclosure relates generally to memory sub-systems and, more specifically, to providing adaptive media management for memory components, such as memory dies.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various examples of the disclosure. The drawings, however, should not be taken to limit the disclosure to the specific examples, but are for explanation and understanding only.

FIG. 1 is a block diagram illustrating an example computing system that includes a memory sub-system, in accordance with some examples.

FIG. 2 is a block diagram of example inner and boundary word line (WL) read level offset tables, in accordance with some examples.

FIG. 3 illustrates a diagram of an example boundary WL offset table, in accordance with some examples.

FIG. 4 illustrates a diagram of operations performed using the media operations manager, in accordance with some examples.

FIG. 5 illustrates a diagram of operations performed using the media operations manager, in accordance with some examples.

FIG. 6 is a block diagram of an example computer system, in accordance with some examples.

### DETAILED DESCRIPTION

The present disclosure configures a memory sub-system controller to perform selection of read level offsets when reading data from a memory device based on one or both temperature and partial block open time conditions. Specifically, when reading a portion of the memory device, the controller determines whether there is a partially programmed block (PB) condition and if reading from a boundary WL. For non-boundary WL reads or when not in a PB condition, the controller performs a default read operation. For boundary WL reads in PB conditions, the controller determines both the open time and effective temperature (e.g., an average or medium temperature measured over a specified prior time period). The controller then applies specific read level offsets retrieved from a lookup table (e.g., a boundary WL offset table) that accounts for both these factors. The lookup table can contain different read level offset values based on various open time ranges and temperature ranges, with generally higher offsets applied for higher temperatures and longer open times. This selective application of temperature-dependent offset values helps prevent high bit error counts and reduces the need for block refresh operations that can degrade system performance. The controller's approach particularly benefits data center solid state drives where blocks can remain open for up to 24 hours and where temperature variations can impact charge migration and read accuracy.

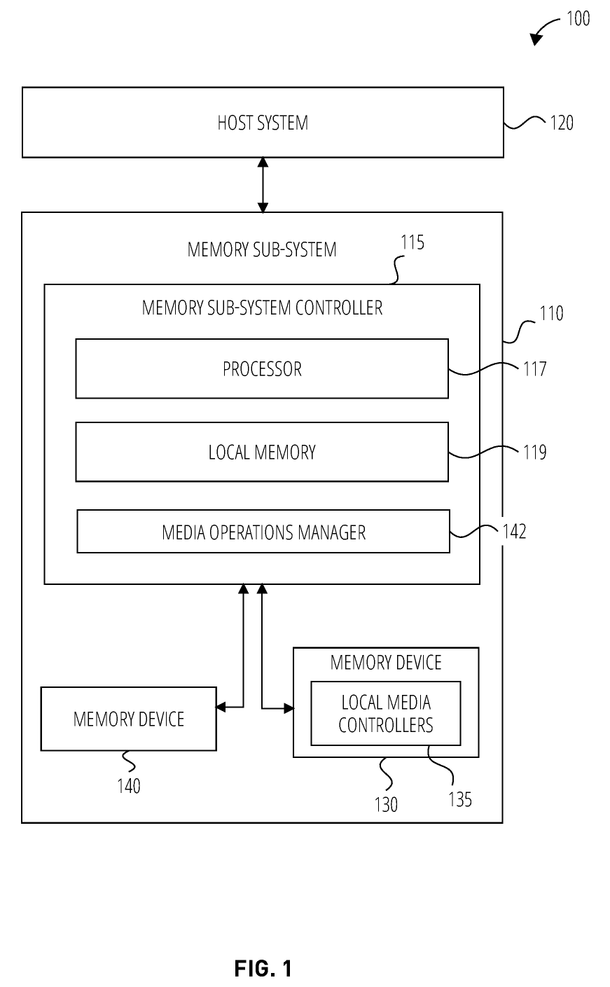

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data.”

The memory sub-system can initiate media management operations, such as a write operation, on host data that is stored on a memory device. In some examples, firmware of the memory sub-system may re-write previously written host data from a location on a memory device to a new location as part of garbage collection management operations. The data that is re-written, for example as initiated by the firmware, is hereinafter referred to as "garbage collection data". “User data” can include host data and garbage collection data. "System data" hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction code (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area that can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND, mNAND), which are raw memory device combined with a local embedded controller for memory management within the same memory device package.

There are challenges in efficiently managing or performing media management operations on typical memory devices. Specifically, certain memory devices, such as NAND flash devices, store data in different WLs. The memory devices can program data into different blocks. Memory blocks that are fully programmed and are closed are referred to as full blocks (FBs). Memory blocks that are not fully programmed (can be referred to as PBs) which can exist in two states. The PB can be open blocks that remain available for writing. The PB can be closed blocks that are no longer available for writing even though they are not fully programmed. In data center solid state drives (SSDs), blocks can remain open for up to one hour before being closed, and when closed, these blocks are not padded with dummy data to fill the remaining space. Such blocks are PBs and are closed preventing additional data from being written to the closed PBs. In order to reduce read disturb errors and other extrinsic defect related errors when reading data, the controllers can apply offsets to the read threshold voltages used to read data from FBs and PBs.

In some cases, the controllers keep track of which regions of the memory components were last programmed. Namely, the controllers can store an indicator of the location of the last page that was programmed to the set of memory components. The WL that includes the last page that was programmed can be referred to as a boundary WL. All other WLs that do not include the last page can be referred to as inner WLs. Reading data from boundary WLs that correspond to a last written page (LWP) may involve adding additional read offset compensation from a boundary WL table.

Conventional approaches to managing PBs in memory devices face significant inefficiencies due to their failure to account for the combined impact of temperature and open time on charge migration. When only considering open time for read level offsets, these systems experience higher bit error counts that necessitate frequent block refresh operations, leading to degraded system performance. The problem is particularly acute as NAND block capacity increases across newer generations, with more WL tiers and sub-blocks making PBs more common. In these cases, the last programmed WL (boundary WL) can become vulnerable to charge loss through Poole-Frenkel diffusion due to having empty neighbor WLs. Traditional systems that rely solely on open-time based read level offsets fail to address the role of temperature in charge migration. This oversight is particularly problematic because higher temperatures can accelerate margin changes in the boundary WL.

The conventional approach's limitations become even more pronounced in data center SSDs and mNAND applications, where PBs can remain open for extended periods between 1 and 24 hours. Without accounting for temperature variations during these extended open periods, the systems may need to perform excessive refresh operations to maintain data integrity, resulting in unnecessary system overhead and reduced performance.

The present disclosure addresses these technical challenges in memory systems by providing a memory sub-system controller that determines and applies temperature-dependent read level offsets for boundary WLs in PB conditions. The controller specifically evaluates both the PB open time and the temperature of the PB to select appropriate read level offsets from a lookup table, such as a boundary WL read offset table. This approach can implement higher offset values for higher temperatures and longer open times, while maintaining flexibility to apply the same offset values across different read levels, temperatures, or open times when appropriate. By considering both temporal and thermal factors, the controller can prevent high raw bit error rates (RBER) and minimize unnecessary block refresh operations that would otherwise degrade system performance. The disclosed controller compensation mechanism can be particularly effective for data center SSDs where partial blocks can remain open for extended periods, such as up to 24 hours, and where temperature variations can impact charge migration through Poole-Frenkel diffusion.

In some examples, a processing device coupled to a memory device work together to manage read operations. The processing device receives read requests and determines whether portions of memory are available for writing data. Based on this determination and temperature information, the processing device retrieves appropriate read offset values to perform the read operations. Specifically, the processing device receives a request to read data from a portion of the memory device and, in response to receiving the request to read the data, determines whether the portion of the memory device is available for writing data. The processing device can retrieve a read offset value based on a temperature associated with the portion of the memory device (and/or an open time associated with the portion of the memory device) in response to determining whether the portion of the memory device is available for writing data. The processing device can then read the data from the portion of the memory device based on the retrieved read offset value.

In some cases, the processing device selectively applies different types of WL offset values. For portions available for writing, the processing device may apply inner WL offset values without boundary WL offsets. When portions are unavailable for writing, both inner and boundary WL offsets may be applied, with the boundary WL offsets being computed based on retrieved temperature-dependent read offset values.

The processing device tracks whether memory portions are available or unavailable for writing through tracking information. Memory blocks can transition from being open to closed based on predetermined time thresholds. The processing device maintains different offset tables for managing read operations. These tables can include separate inner WL offset tables and boundary WL offset tables containing read level offsets for different scenarios. The boundary WL offset table is particularly structured to handle different open time ranges, with each range associated with multiple temperature ranges.

For temperature-dependent operations, the processing device can store and compute temperature measurements over time intervals. When reading from boundary WLs of PBs, the processing device considers both the open time and temperature information to select appropriate read level offsets. The offset tables can be organized to accommodate different temperature ranges, with each range associated with specific read level offset values. Higher temperatures and longer open times generally correspond to larger offset values to compensate for increased charge migration. The processing device can compute open times for PBs by tracking the elapsed time since initial programming. This information, combined with temperature data, allows the system to access the appropriate offset values from the boundary WL offset table.

Though various examples are described herein as being implemented with respect to a memory sub-system (e.g., a controller of the memory sub-system), some or all of the portions of an embodiment can be implemented with respect to a host system, such as a software application or an operating system of the host system.

FIG. 1 illustrates an example computing system 100 that includes a memory sub-system 110, in accordance with some examples. The memory sub-system 110 can include media, such as one or more volatile memory devices (e.g., memory device 140), one or more non-volatile memory devices (e.g., memory device 130), or a combination of such.

In some examples, the memory device 130, including one or more portions (e.g., one or more WLs, one or more WL groups (WLGs), one or more blocks, one or more memory dies, and/or one or more pages) or group of memory components including the memory device 130, can be associated with a first reliability (capability) grade, value, measure, or lifetime program-erase count (PEC). The terms “reliability grade,” “value,” and “measure” are used interchangeably throughout and can have the same meaning. The memory device 140 (e.g., one or more WLs, one or more WLGs, one or more blocks, one or more memory dies, and/or one or more pages) or group of memory components, including the memory device 140, can be associated with a second reliability (capability) grade, value, measure, or lifetime PEC. In some examples, each memory component (memory device 130 and memory device 140) can store respective configuration data that specifies the respective reliability grade and lifetime PEC and current PEC and/or other conditions. In some examples, a memory or register can be associated with all of the memory components (memory device 130 and memory device 140) and can store a table that maps different groups, portions, bins, or sets of the memory device 130 and memory device 140 to respective reliability grades, conditions, lifetime PEC values, and/or current PEC values.

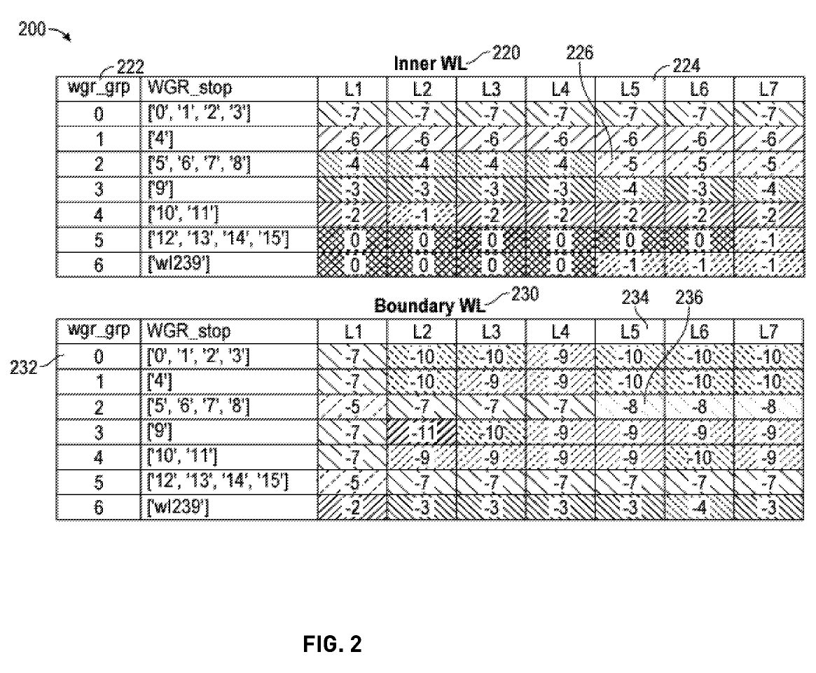

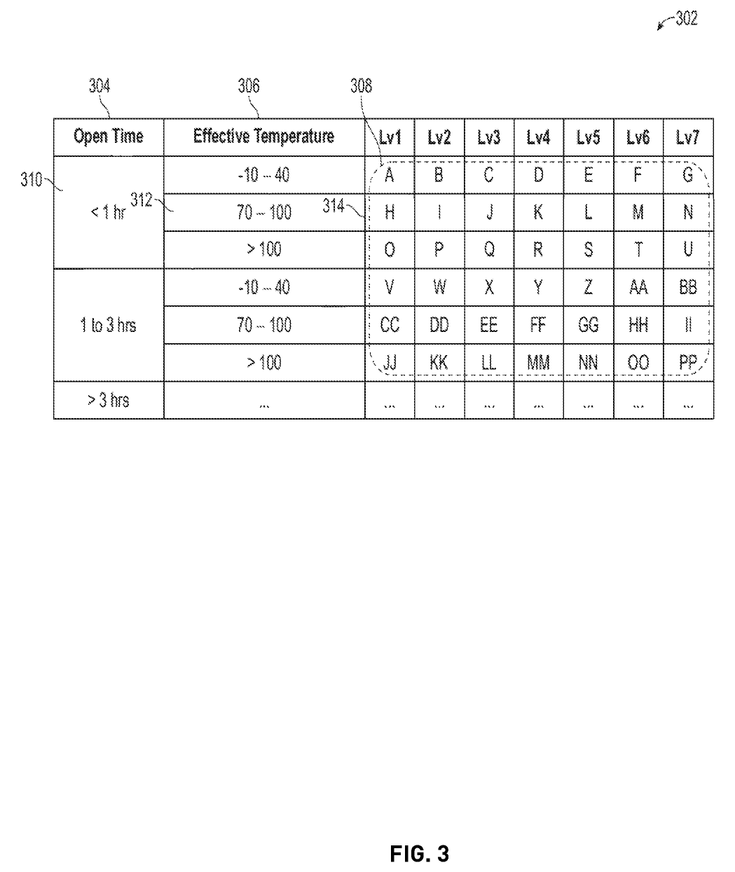

In some cases, a memory or register (e.g., included as part of local memory 119) can store an inner WL offset table and a boundary WL offset table, such as an inner WL offset table 220, a boundary WL offset table 230, and/or the read level offset table shown in diagram 302 (FIG. 3). In some cases, the inner WL offset table and the boundary WL offset table can be combined into a single table. For example, as shown in diagram 200 of FIG. 2, the inner WL offset table 220 can store various read level offsets that can be applied to a read threshold voltage when reading one or more inner WLs. Namely, a first WL or WLG 222 can be associated with a first set of read level offsets 224. Each read level offset in the first set of read level offsets 224 can represent a different amount of offset to apply to the read threshold voltage when reading different levels of tri-level cell (TLC) storage (or other multi-level cell storage). Namely, when reading level 1 from the TLC storage in a WL that is part of a first WLG (e.g., any WL specified by the WGR_stop for WGR_grp 4, and specifically WLG_stop ‘10’ or WLG_stop “11’), a -2 DAC offset can be applied, when reading level 2 from the TLC storage in the WL part of the first WLG, a -1 DAC offset can be applied, and when reading levels 3-7 from the TLC storage in WL that is part of the first WLG, a -2 DAC offset can be applied. The first column shown in FIG. 2 represents WLG grouping columns. The actual WLGs are defined in the second column WLG_stop. If any WL is in a given WLG_stop, it may use the specified read offsets for each level in that WLG. Any WL in WLG_stop 10 or WLG_stop 11 may have to use the offset corresponding to the WGR_GRP 4 group.

A second WL or WLG 222 can be associated with a second set of read level offsets 224. Each read level offset in the second set of read level offsets 224 can represent a different amount of offset to apply to the read threshold voltage when reading different levels of TLC storage. Namely, when reading levels 1-4 from the TLC storage in the second WLG (e.g., word line group 6), and when reading levels 5-7 from the TLC storage in the second WLG, a -1 DAC offset can be applied.

A boundary WL offset table 230 can store various read level offsets that can be applied to a read threshold voltage when reading one or more boundary WLs (e.g., WLs that include a last programmed portion or page or WL). Namely, a first WL or WLG 232 can be associated with a second set of read level offsets 234. Each read level offset in the third set of read level offsets 234 can represent a different amount of offset to apply to the read threshold voltage when reading different levels of TLC storage (or other multi-level cell storage). These offsets can be the same or different from those mentioned with respect to the inner WL offset table 220. For example, a read level offset 226 in the inner WL offset table 220 for a particular WL and for a particular level of the TLC storage can be a first value of -5 DAC. A read level offset 236 in the boundary WL offset table 230 for the same particular WL and for the same particular level of the TLC storage can be a second value of -8 DAC. The read level offset table shown in diagram 302 can represent one implementation of the boundary WL offset table 230.

In some cases, a media operations manager 142 determines that the request to read the portion of the set of memory components corresponds to a PB (open or closed). In such cases, the media operations manager 142 can access a buffer or storage to identify which WL is indicated to store the last programmed portion or page. The media operations manager 142 can determine a level of the TLC storage that is being read and retrieve the read level offset stored in the inner WL offset table 220. The media operations manager 142 obtains a read threshold voltage for reading data from the portion and modifies the read threshold voltage by the read level offset retrieved from the inner WL offset table 220. The media operations manager 142 can then read each inner WL of the PB using the same modified read threshold voltage. Namely, the media operations manager 142 can read each WL of the PB excluding the identified WL (e.g., the boundary WL) that includes the last programmed portion or page using the read threshold voltage that has been modified by the corresponding value in the inner WL offset table 220.

The media operations manager 142 can obtain the read level offset stored in the boundary WL offset table 230 for the read level being read from the identified WL that includes the last programmed portion or page or last programmed WL. Namely, the media operations manager 142 can use the corresponding values stored in the boundary WL offset table 230 to read data from the boundary WL of the PB. In some cases, the media operations manager 142 can combine (e.g., add) the read level offset stored in the boundary WL offset table 230 with the read level offset that was used to read the inner WL to generate a second read level offset. In some cases, a table (a separate table) can be maintained that includes the already combined values so that the media operations manager 142 does not have to combine the read level offset stored in the boundary WL offset table 230 with the read level offset that was used to read the inner WL to generate the second read level offset (e.g., the second read level offset can be precomputed and stored in a table). The media operations manager 142 can then read the identified boundary WL of the PB that includes the last programmed portion or page or last programmed WL using the read threshold voltage adjusted by the second read level offset.

In some examples, the media operations manager 142 can retrieve read level offsets from a boundary WL offset table based on both open time ranges and temperature ranges. Specifically, when reading a boundary WL of a PB, the media operations manager 142 accesses the boundary WL offset table, such as the table shown in diagram 302, using the determined open time range and effective temperature range to obtain the appropriate read level offset value. For example, the media operations manager 142 can select the appropriate offset value from the table shown in diagram 302 by first identifying the relevant open time range (such as less than 1 hour, 1 to 3 hours, or greater than 3 hours) and then selecting the corresponding temperature range (-10 to 40°C, 70 to 100°C, or greater than 100°C). The retrieved offset value can then be combined with the inner WL offset that was previously used, generating a final read level offset for the boundary WL. In some implementations, these combined offset values may be pre-computed and stored in a separate table to improve operational efficiency. The media operations manager 142 then applies this final read level offset to adjust the read threshold voltage when reading data from the boundary WL of the PB.

Referring back to FIG. 1, a memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some examples, the host system 120 is coupled to different types of memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NAND flash memory and write-in-place memory, such as a 3D cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130, 140 can include one or more arrays of memory cells. One type of memory cell, for example, single level cells (SLCs), can store one bit per cell. Other types of memory cells (e.g., including multi-level cell storage), such as multi-level cells (MLCs), tri-level cells (TLCs), quad-level cells (QLCs), and penta-level cells (PLCs), can store multiple bits per cell. In some examples, each of the memory devices 130, 140 can include one or more arrays of memory cells such as SLCs, MLCs, TLCs, QLCs, or any combination of such. In some examples, a particular memory device can include an SLC portion, and an MLC portion, a TLC portion, or a QLC portion of memory cells. The memory cells of the memory devices 130, 140 can be grouped as pages that can refer to a logical unit of the memory device used to store data. With some types of memory (e.g., NAND), pages can be grouped to form blocks or block stripes (BSs). As used herein, a block comprising SLCs can be referred to as a SLC block, a block including MLCs can be referred to as an MLC block, a block comprising TLCs can be referred to as a TLC block, and a block comprising QLCs can be referred to as a QLC block.

Although non-volatile memory components such as NAND-type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, and electrically erasable programmable read-only memory (EEPROM).

A memory sub-system controller 115 (or controller 115 for simplicity) can communicate with the memory devices 130, 140 to perform operations such as reading data, writing data, or erasing data (e.g., performing garbage collection (GC) operations) at the memory devices 130, 140 and other such operations. The memory sub-system controller 115 can include hardware such as one or more integrated circuits and/or discrete components, a buffer memory, or a combination thereof. The hardware can include digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some examples, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another example, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, GC operations, error detection and ECC operations, encryption operations, caching operations, and address translations between a logical address (e.g., logical block address (LBA), namespace) and a physical memory address (e.g., physical block address in a physical address space of the memory device 130 or memory device 140) that are associated with the memory devices 130, 140. The memory sub-system controller 115 can further include host interface circuitry to communicate with the host system 120 via the physical host interface. The host interface circuitry can convert the commands received from the host system 120 into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some examples, the memory sub-system 110 can include a cache or buffer (e.g., DRAM) and address circuitry (e.g., a row decoder and a column decoder) that can receive an address from the memory sub-system controller 115 and decode the address to access the memory devices 130, 140.

In some examples, the memory device 130 includes local media controllers 135 that operate in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some examples, a memory device 130 is a managed memory device, which is a raw memory device combined with a local controller (e.g., local media controller 135) for media management within the same memory device package. An example of a managed memory device is a managed NAND (MNAND) device. Any operation discussed as being performed by the memory sub-system controller 115 can be similarly performed by the local media controllers 135 and vice versa.

The media operations manager 142 can perform selection of read level offsets when reading data from a memory device 130 based on whether a block (or portion) is open or closed. Specifically, when reading a portion of the memory device 130, the media operations manager 142 evaluates both the PB open time and the temperature of the PB to select appropriate read level offsets from a lookup table, such as a boundary WL read offset table. This approach can implement higher offset values for higher temperatures and longer open times, while maintaining flexibility to apply the same offset values across different read levels, temperatures, or open times when appropriate. By considering both temporal and thermal factors, the media operations manager 142 can prevent high RBER and minimize unnecessary block refresh operations that would otherwise degrade system performance. The media operations manager 142 compensation mechanism can be particularly effective for data center SSDs where partial blocks can remain open for extended periods, such as up to 24 hours, and where temperature variations can impact charge migration through Poole-Frenkel diffusion.

Any discussion with respect to the memory device 130 can similarly be applied to the memory device 140. Any function pertaining to the local media controllers 135 can, in some cases, be performed by the memory sub-system controller 115.

FIG. 3 illustrates a diagram 302 of an example boundary WL offset table, in accordance with some examples. Namely, FIG. 3 illustrates a boundary WL offset table structure organized by open time ranges 304 and temperature ranges 306. The table includes multiple columns representing open time ranges and effective temperature ranges, respectively.

The open time ranges 304 can be divided into categories such as less than 1 hour, 1 to 3 hours, and greater than 3 hours. For each open time range in the open time ranges 304, there are corresponding temperature ranges 306 organized into bands like -10 to 40 degrees, 70 to 100 degrees, and greater than 100 degrees. The table shown in the diagram 302 can contain read level offset values (read levels 308) (represented by letters A through PP) for different levels (Lv1 through Lv7) of TLC storage. These offset values can be organized in a way that generally follows certain patterns where higher levels can correspond to larger offset values; higher temperatures can require greater read level offsets; and longer open times can correspond to larger offset values.

The table structure allows for flexibility in offset value assignment, where some offset values may be identical across different levels, temperatures, or open times. For example, offset values like B and H could represent the same voltage adjustment, while other values like G and U might differ to account for varying conditions. This organization enables the media operations manager 142 to efficiently retrieve appropriate read level offsets by first identifying the relevant open time range and temperature range, then selecting the corresponding offset value for the specific TLC level being read.

For example, the media operations manager 142 can receive a read request (e.g., from the host system 120) to access data from a portion of the memory device 130. Upon receiving this request, the media operations manager 142 first checks the tracking information to determine if the portion being read corresponds to a PB. This determination can involve verifying whether the block is not fully programmed and is either still open for writing or has been closed but contains un-programmed space. After confirming the PB condition, the media operations manager 142 can check whether the specific WL being accessed is a boundary WL. For example, the media operations manager 142 can access stored indicators that track the location of the LWP in the memory device 130. The boundary WL can be identified as the WL containing the LWP.

To compute the open time of the PB, the media operations manager 142 can track the elapsed time since the block was initially programmed with data. Namely, the media operations manager 142 can compute a difference between a current timestamp and a timestamp stored in association with the block indicating the time when data was first programmed into the block. This difference represents the elapsed time since data was initially programmed into the block. The media operations manager 142 can maintain records of when blocks transition between states, which is important for data center SSDs where blocks can remain open for extended periods up to 24 hours.

For determining the effective temperature, the media operations manager 142 can access stored temperature measurements collected over a specified time interval. The media operations manager 142 can compute an average of these multiple temperature measurements to establish the effective temperature value that will be used for selecting the appropriate read level offset. With both the open time and effective temperature calculated, the media operations manager 142 accesses the boundary WL offset table shown in diagram 302. The media operations manager 142 can first identify which open time range category of the open time ranges 304 applies to the computed open time, such as whether the open time of the PB falls under less than 1 hour, 1 to 3 hours, or greater than 3 hours. For example, the media operations manager 142 can determine that the open time of the block corresponds to the individual open time range 310.

Within the identified open time range (e.g., the individual open time range 310), the media operations manager 142 can then determine which temperature range category matches the computed effective temperature, selecting from ranges such as -10 to 40 degrees, 70 to 100 degrees, or greater than 100 degrees. For example, the media operations manager 142 can determine that the effective temperature of the PB corresponds to the individual temperature range 312. The intersection of the selected open time range and temperature range in the table leads to a specific set of read level offsets 314 corresponding to different levels of TLC storage. These offset values are organized to provide increasingly larger compensations for higher temperatures and longer open times.

The media operations manager 142 retrieves the specific read level offset value from this intersection based on which TLC level is being read. For example, if reading from level 1 (Lv1) in conditions of less than 1 hour open time and -10 to 40 degree temperature range, the media operations manager 142 can retrieve offset value "A" from the table. In some implementations, the retrieved boundary WL offset value is combined with the inner WL offset that was previously used for reading inner WLs. This combination generates a final read level offset that accounts for both the standard read requirements and the additional compensation needed for boundary WL conditions.

Finally, the media operations manager 142 applies this retrieved offset value to adjust the read threshold voltage when reading data from the boundary WL of the PB. This time and/or temperature-dependent offset helps prevent high bit error counts and reduces the need for block refresh operations that would otherwise degrade system performance.

The boundary WL offset table of diagram 302 allows for flexibility in assigning offset values, where identical offset values can be used across different scenarios. For example, when reading from different TLC storage levels under certain conditions, the same offset value might be appropriate, such as offset value "B" being used for both level 2 and level 3 reads under the same temperature and open time conditions. Similarly, different temperature ranges might require the same compensation in some cases, like offset value "H" being applied for both the 70-100 degree range and the >100 degree range when other conditions align. This flexibility extends to open time ranges as well, where the same offset value could be appropriate for both a 1-hour and 3-hour open time if the temperature effects and level characteristics warrant similar compensation.

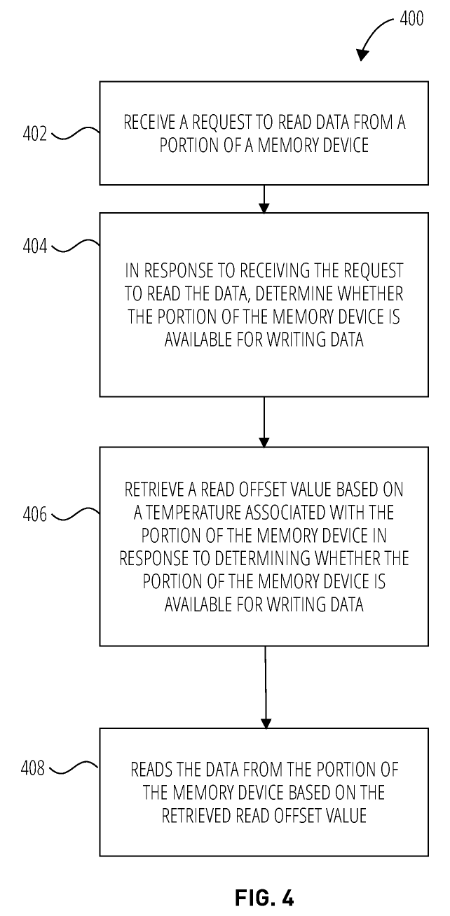

FIG. 4 illustrates a diagram 400 of operations performed using the media operations manager 142, in accordance with some examples. The method or process of diagram 400 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 400 is performed by the memory sub-system controller 115, local media controllers 135, and/or subcomponents of the memory sub-system controller 115 and/or local media controllers 135 of FIG. 1. In these examples, the method or process of diagram 400 can be performed, at least in part, by the media operations manager 142. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example. Other process flows are possible.

Referring now to FIG. 4, the method begins at operation 402 with the media operations manager 142 receiving a request to read data from a portion of the memory device 130. At operation 404, the media operations manager 142, in response to receiving the request to read the data, determines whether the portion of the memory device 130 is available for writing data. At operation 406, the media operations manager 142 retrieves a read offset value based on a temperature associated with the portion of the memory device in response to determining whether the portion of the memory device is available for writing data and, at operation 408, reads the data from the portion of the memory device based on the retrieved read offset value.

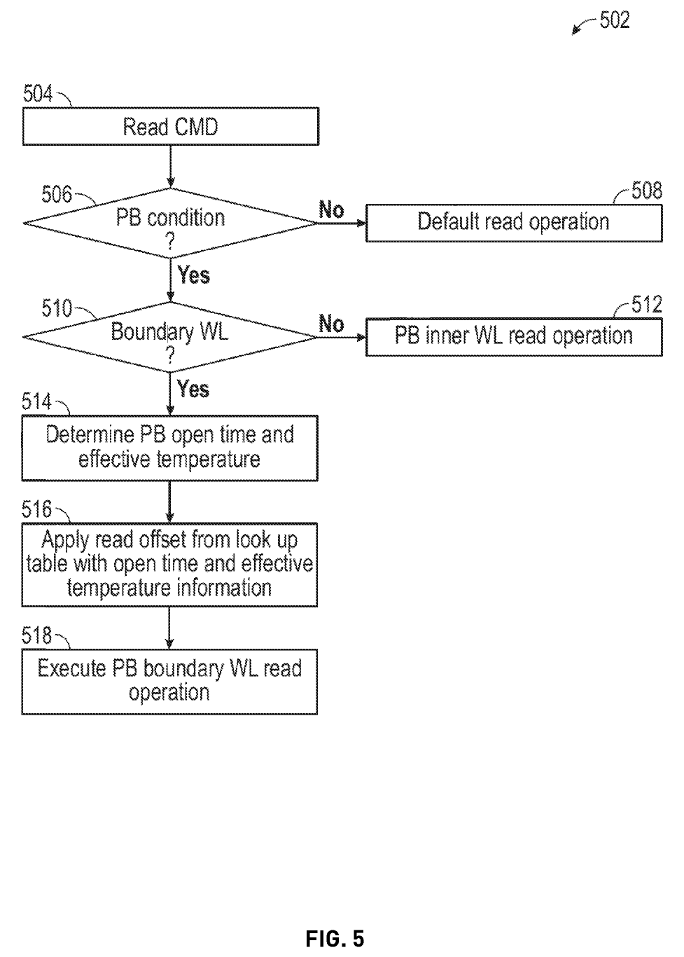

FIG. 5 illustrates a diagram 502 of operations performed using the media operations manager 142, in accordance with some examples. The method or process of diagram 502 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 502 is performed by the memory sub-system controller 115, local media controllers 135, and/or subcomponents of the memory sub-system controller 115 and/or local media controllers 135 of FIG. 1. In these examples, the method or process of diagram 502 can be performed, at least in part, by the media operations manager 142. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example. Other process flows are possible.

Referring now to FIG. 5, the method begins at operation 504 with the media operations manager 142 receiving a read command from a host system 120. At operation 506, the media operations manager 142 determines whether there is a PB condition. For example, at operation 506, the media operations manager 142 determines whether the portion of memory being read corresponds to a PB, such as by checking if the block being read is not fully programmed but is either open for writing or closed to writing. Specifically, the media operations manager 142 can access tracking information that indicates whether the portion is available or unavailable for writing data. For example, if the tracking information shows the block is not fully programmed and either is an open block that remains available for writing additional data, or is a closed block that is no longer available for writing even though it is not fully programmed, then the media operations manager 142 determines there is a PB condition.

In data center SSDs, this determination is particularly important since blocks can remain open for extended periods (up to 24 hours) before being closed, and when closed, these blocks are not padded with dummy data to fill the remaining space. The media operations manager 142 uses this PB condition check to determine whether to apply standard read operations or to proceed with specialized read operations that may need time and/or temperature-dependent boundary WL offset values.

If no PB condition exists at operation 506, the media operations manager 142 proceeds to operation 508 where a default read operation is performed. Namely, if no PB condition exists at operation 506, the media operations manager 142 proceeds to operation 508 where a default read operation is performed without applying any special temperature-dependent or boundary WL offset values. In this default read operation, the media operations manager 142 reads data from the memory device 130 using standard read threshold voltages without the additional compensation mechanisms that would be required for PBs. This default read operation can be used for FBs where all WLs are programmed and the block is closed, meaning there are no empty neighbor WLs that could lead to charge loss through Poole-Frenkel diffusion. Since these blocks may not face the same charge migration challenges as PBs, they may not require the specialized time/temperature-dependent read level offset compensation that may need to be applied to boundary WLs in PB conditions. The default read operation represents the standard read process that occurs when reading from memory blocks that are in their normal, fully programmed state, where concerns about charge loss due to empty neighbor WLs and temperature-dependent effects are not present.

If a PB condition exists at operation 506, the media operations manager 142 proceeds to perform operation 510 where the media operations manager 142 determines whether the read operation involves a boundary WL. If the portion being read does not correspond to a boundary WL, the media operations manager 142 proceeds to operation 512 where a PB inner WL read operation is performed. For example, if the portion being read does not correspond to a boundary WL, the media operations manager 142 proceeds to operation 512 where a PB inner WL read operation is performed using the inner WL offset table. The inner WL offset table stores various read level offsets that are applied to read threshold voltages when reading from inner WLs. Namely, when reading from inner WLs, the media operations manager 142 retrieves specific read level offsets from the inner WL offset table based on the WLG being accessed. Each WLG in the inner WL offset table can be associated with different sets of read level offsets corresponding to different levels of TLC storage. The inner WL offset table organizes these offsets by WL groups, where each WLG is associated with specific offset values. For instance, a first WLG may use one set of DAC offsets for different TLC levels (like -2 DAC for level 1, -1 DAC for level 2, and -2 DAC for levels 3-7), while a second WLG may use different offset values (such as -1 DAC for levels 1-4 and -1 DAC for levels 5-7).

The media operations manager obtains a read threshold voltage for reading data from the portion and modifies it by the read level offset retrieved from the inner WL offset table. It then reads each inner WL of the PB using this same modified read threshold voltage. This approach ensures consistent read operations across all inner WLs of the PB without applying the additional boundary WL offset compensation that would be needed for boundary WLs.

If reading from a boundary WL as determined by the operation 510, the media operations manager 142 proceeds to operation 514 where the media operations manager 142 determines the PB open time and effective temperature (e.g., the average or medium temperature over the past threshold time interval, such as 1 minute or 1 hour). Namely, if reading from a boundary WL, the media operations manager 142 determines both the PB open time and effective temperature at operation 514 through several methods. For determining open time, the media operations manager 142 can compute the elapsed time since the PB was initially programmed with data. The tracking information maintains records of when blocks transition from open to closed states. For data center SSDs, the media operations manager 142 monitors blocks that can remain open for periods between 1 and 24 hours. For determining effective temperature, the media operations manager 142 can store multiple temperature measurements of the memory device 130 over specified time intervals. These measurements are used to compute an average temperature value. The media operations manager 142 can choose to use a medium temperature measured over certain time periods (like 1 minute or 1 hour) as the effective temperature.

The media operations manager 142 uses this combined timing and temperature data to access the appropriate offset values from the boundary WL offset table, which is organized by both open time ranges (e.g., <1 hr, 1-3 hrs, >3 hrs) and temperature ranges (e.g., -10 to 40°C, 70 to 100°C, >100°C). This allows the media operations manager 142 to select read level offsets that account for both temporal and thermal effects on charge migration.

At operation 516, the media operations manager 142 applies read offset values from a lookup table (e.g., the boundary WL offset table shown in diagram 302 of FIG. 3) based on the determined open time and effective temperature information. Finally, at operation 518, the media operations manager 142 executes a PB boundary WL read operation using the retrieved read offset values.

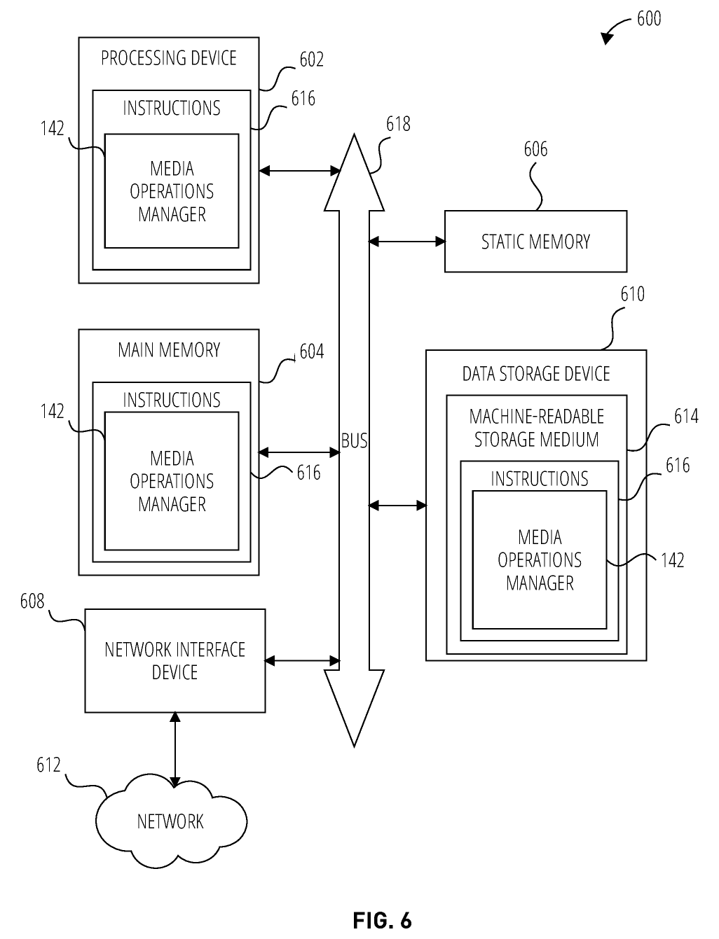

FIG. 6 illustrates an example machine in the form of a computer system 600 within which a set of instructions can be executed for causing the machine to perform any one or more of the methodologies discussed herein. In some examples, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., ROM, flash memory, DRAM such as SDRAM or Rambus DRAM (RDRAM), etc.), a static memory 606 (e.g., flash memory, static random access memory (SRAM), etc.), and a data storage device 610, which communicate with each other via a bus 618.

The processing device 602 represents one or more general-purpose processing devices such as a microprocessor, a central processing unit, or the like. More particularly, the processing device 602 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 602 can also be one or more special-purpose processing devices such as an application-specific integrated circuit (ASIC), a field programmable gate array (FPGA), a digital signal processor (DSP), a network processor, or the like. The processing device 602 is configured to execute instructions 616 for performing the operations and steps discussed herein. The computer system 600 can further include a network interface device 608 to communicate over a network 612.

The data storage device 610 can include a machine-readable storage medium 614 (also known as a computer-readable medium) on which is stored one or more sets of instructions 616 or software embodying any one or more of the methodologies or functions described herein. The instructions 616 can also reside, completely or at least partially, within the main memory 604 and/or within the processing device 602 during execution thereof by the computer system 600, the main memory 604 and the processing device 602 also constituting machine-readable storage media. The machine-readable storage medium 614, data storage device 610, and/or main memory 604 can correspond to the memory sub-system 110 of FIG. 1.

In one example, the instructions 616 include instructions to implement functionality corresponding to providing block failure protection for a zone memory sub-system as described herein. While the machine-readable storage medium 614 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.

Example 1. A system comprising: a memory device; and a processing device, operatively coupled to the memory device, configured to perform operations comprising: receiving a request to read data from a portion of the memory device; in response to receiving the request to read the data, determining whether the portion of the memory device is available for writing data; retrieving a read offset value based on a temperature associated with the portion of the memory device in response to determining whether the portion of the memory device is available for writing data; and reading the data from the portion of the memory device based on the retrieved read offset value.

Example 2. The system of Example 1, the operations comprising: selectively applying boundary word line (WL) offset values to read one or more WLs of the portion of the memory device in addition to applying inner WL offset values in response to determining whether the portion of the memory device is available for writing data, the boundary WL offset values being computed based on the retrieved read offset value.

Example 3. The system of Example 2, the operations comprising: in response to determining the portion is available for writing data, applying the inner WL offset values without boundary WL offset values to read one or more WLs of the portion of the memory device; and in response to determining the portion is unavailable for writing data, applying both inner WL offset values and boundary WL offset values to read the one or more WLs of the portion of the memory device.

Example 4. The system of any one of Examples 1-3, wherein the portion is determined to be available for writing data in response to determining that the portion comprises an open memory block, wherein the portion is determined to be unavailable for writing data in response to determining that the portion comprises a closed memory block.

Example 5. The system of Example 4, the operations comprising: accessing tracking information in response to receiving the request, the tracking information indicating whether the portion is available or unavailable for writing the data; and reading data from the portion of the memory device using at least one of inner WL offset values or boundary WL offset values computed based on the retrieved read offset value.

Example 6. The system of Example 5, wherein the closed memory block is a partially programmed block (PB).

Example 7. The system of Example 6, wherein the PB transitions from being an open memory block to being a closed memory block in response to determining that a time period during which the open memory block has remained open exceeds a predetermined threshold.

Example 8. The system of any one of Examples 1-7, wherein the portion comprises a plurality of word lines (WLs), the plurality of WLs comprising one or more inner WLs including an individual WL and a boundary WL, wherein inner WL offset values are retrieved from an inner WL offset table, and wherein boundary WL offset values are retrieved from a boundary WL offset table.

Example 9. The system of Example 8, the operations comprising: storing the inner WL offset table comprising a first plurality of read level offsets; and storing the boundary WL offset table comprising a second plurality of read level offsets, the boundary WL offset table representing a set of read level offsets for reading data from one or more WLs of a partially programmed block (PB).

Example 10. The system of Example 9, the operations comprising: reading a first set of data from the one or more inner WLs of the portion using a first read level offset retrieved from the inner WL offset table; and reading a second set of data from the boundary WL of the portion using a combined read level offset generated based on the first read level offset and a second read level offset retrieved from the boundary WL offset table.

Example 11. The system of any one of Examples 9-10, wherein the inner WL offset table associates a first WL group (WLG) with a first set of read level offsets corresponding to different levels of tri-level cell (TLC) storage, wherein the inner WL offset table associates a second WLG with a second set of read level offsets corresponding to the different levels of the TLC storage, wherein the boundary WL offset table associates the first WLG with a third set of read level offsets corresponding to the different levels of the TLC storage, and wherein the boundary WL offset table associates the second WLG with a fourth set of read level offsets corresponding to the different levels of the TLC storage.

Example 12. The system of any one of Examples 1-11, wherein the read offset value is retrieved from a boundary word line (WL) offset table.

Example 13. The system of Example 12, wherein the boundary WL offset table comprises a plurality of open time ranges, a first open time range of the plurality of open time ranges being associated with a first plurality of temperature ranges, a second open time range of the plurality of open time ranges being associated with a second plurality of temperature ranges.

Example 14. The system of Example 13, wherein a first temperature range of the first plurality of temperature ranges is associated with a first plurality of read level offset values each associated with a different read level of different read levels of tri-level cell (TLC) storage, wherein a second temperature range of the second plurality of temperature ranges is associated with a second plurality of read level offset values each associated with the different read level of the different read levels of the TLC storage.

Example 15. The system of Example 14, the operations comprising: in response to receiving the request to read the data and in response to determining that the portion of the memory device associated with the request to read the data corresponds to a boundary WL of a partially programmed block (PB), computing an open time associated with the PB and a temperature associated with the PB, the open time representing an amount of time that has elapsed since the PB has initially been programmed with data.

Example 16. The system of Example 15, the operations comprising: accessing the boundary WL offset table based on the open time and the temperature to retrieve a corresponding set of read level offsets from the boundary WL offset table.

Example 17. The system of any one of Examples 15-16, the operations comprising: storing a plurality of temperature measurements of the memory device over a time interval; computing an average of the plurality of temperature measurements; and using the computed average of the plurality of temperature measurements as the temperature associated with the PB.

Example 18. The system of any one of Examples 1-17, wherein the memory device comprises a three-dimensional (3D) NAND device.

Example 19. At least one non-transitory machine-readable storage medium comprising instructions that, when executed by a processing device, cause the processing device to perform operations comprising: receiving a request to read data from a portion of a memory device; in response to receiving the request to read the data, determining whether the portion of the memory device is available for writing data; retrieving a read offset value based on a temperature associated with the portion of the memory device in response to determining whether the portion of the memory device is available for writing data; and reading the data from the portion of the memory device based on the retrieved read offset value.

Example 20. A method comprising: receiving a request to read data from a portion of a memory device; in response to receiving the request to read the data, determining whether the portion of the memory device is available for writing data; retrieving a read offset value based on a temperature associated with the portion of the memory device in response to determining whether the portion of the memory device is available for writing data; and reading the data from the portion of the memory device based on the retrieved read offset value.

The term “coupled with” generally refers to a connection between components, which can be an indirect communicative connection or direct communicative connection (e.g., without intervening components), whether wired or wireless, including connections such as electrical, optical, magnetic, and the like.

“System data” hereinafter refers to data that is created and/or maintained by the memory sub-system for performing operations in response to host requests and for media management.

“User data” hereinafter generally refers to host data and garbage collection data.

“Read disturb” refers to a phenomenon where repeated read operations on a specific WL in a NAND flash memory block cause unintended changes in the threshold voltages of adjacent cells on unselected WLs within the same block. This effect can potentially lead to data corruption in neighboring cells if left unmanaged, necessitating periodic data refresh or block relocation (folding) operations to maintain data integrity in NAND-based storage devices.

"Partially programmed block (PB)" refers to memory blocks that are not fully programmed and remain open with one or more sub-blocks that are empty and ready to be programmed. This is in contrast to full blocks (FBs) which are memory blocks that are fully programmed and closed. PBs require special handling for read operations, including the application of different read level offsets for inner word lines (WLs) and boundary WLs to reduce read disturb errors and other extrinsic defect related errors when reading data from these blocks.

"Inner WL" refers to any WL in a PB that does not contain the last programmed page. Inner WLs may require specific read level offsets retrieved from an inner WL offset table to reduce read disturb errors and other extrinsic defect related errors when reading data.

"Boundary WL" refers to the WL in a PB that contains the last programmed page. Boundary WLs may require special handling during read operations where both the inner WL offset and a modified boundary WL offset are combined to generate the read level offset used to read data, in order to reduce RBER associated with reading the last programmed portion.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, examples of the disclosure have been described with reference to specific examples thereof. It will be evident that various modifications can be made thereto without departing from the broader scope of examples of the disclosure as set forth in the following claims. The specification and drawings are, accordingly, to be regarded in an illustrative sense rather than a restrictive sense.

1. A system comprising:
a memory device; and
a processing device, operatively coupled to the memory device, configured to perform operations comprising:
receiving a request to read data from a portion of the memory device;
in response to receiving the request to read the data, determining whether the portion of the memory device is available for writing data;
retrieving a read offset value based on a temperature associated with the portion of the memory device in response to determining whether the portion of the memory device is available for writing data; and
reading the data from the portion of the memory device based on the retrieved read offset value.

2. The system of claim 1, the operations comprising:
selectively applying boundary word line (WL) offset values to read one or more WLs of the portion of the memory device in addition to applying inner WL offset values in response to determining whether the portion of the memory device is available for writing data, the boundary WL offset values being computed based on the retrieved read offset value.

3. The system of claim 2, the operations comprising:
in response to determining the portion is available for writing data, applying the inner WL offset values without boundary WL offset values to read one or more WLs of the portion of the memory device; and
in response to determining the portion is unavailable for writing data, applying both inner WL offset values and boundary WL offset values to read the one or more WLs of the portion of the memory device.

4. The system of claim 1, wherein the portion is determined to be available for writing data in response to determining that the portion comprises an open memory block, wherein the portion is determined to be unavailable for writing data in response to determining that the portion comprises a closed memory block.

5. The system of claim 4, the operations comprising:
accessing tracking information in response to receiving the request, the tracking information indicating whether the portion is available or unavailable for writing the data; and
reading data from the portion of the memory device using at least one of inner WL offset values or boundary WL offset values computed based on the retrieved read offset value.

6. The system of claim 5, wherein the closed memory block is a partially programmed block (PB).

7. The system of claim 6, wherein the PB transitions from being an open memory block to being a closed memory block in response to determining that a time period during which the open memory block has remained open exceeds a predetermined threshold.

8. The system of claim 1, wherein the portion comprises a plurality of word lines (WLs), the plurality of WLs comprising one or more inner WLs including an individual WL and a boundary WL, wherein inner WL offset values are retrieved from an inner WL offset table, and wherein boundary WL offset values are retrieved from a boundary WL offset table.

9. The system of claim 8, the operations comprising:
storing the inner WL offset table comprising a first plurality of read level offsets; and
storing the boundary WL offset table comprising a second plurality of read level offsets, the boundary WL offset table representing a set of read level offsets for reading data from one or more WLs of a partially programmed block (PB).

10. The system of claim 9, the operations comprising:
reading a first set of data from the one or more inner WLs of the portion using a first read level offset retrieved from the inner WL offset table; and
reading a second set of data from the boundary WL of the portion using a combined read level offset generated based on the first read level offset and a second read level offset retrieved from the boundary WL offset table.

11. The system of claim 9, wherein the inner WL offset table associates a first WL group (WLG) with a first set of read level offsets corresponding to different levels of tri-level cell (TLC) storage, wherein the inner WL offset table associates a second WLG with a second set of read level offsets corresponding to the different levels of the TLC storage, wherein the boundary WL offset table associates the first WLG with a third set of read level offsets corresponding to the different levels of the TLC storage, and wherein the boundary WL offset table associates the second WLG with a fourth set of read level offsets corresponding to the different levels of the TLC storage.

12. The system of claim 1, wherein the read offset value is retrieved from a boundary word line (WL) offset table.

13. The system of claim 12, wherein the boundary WL offset table comprises a plurality of open time ranges, a first open time range of the plurality of open time ranges being associated with a first plurality of temperature ranges, a second open time range of the plurality of open time ranges being associated with a second plurality of temperature ranges.

14. The system of claim 13, wherein a first temperature range of the first plurality of temperature ranges is associated with a first plurality of read level offset values each associated with a different read level of different read levels of tri-level cell (TLC) storage, wherein a second temperature range of the second plurality of temperature ranges is associated with a second plurality of read level offset values each associated with the different read level of the different read levels of the TLC storage.

15. The system of claim 14, the operations comprising:
in response to receiving the request to read the data and in response to determining that the portion of the memory device associated with the request to read the data corresponds to a boundary WL of a partially programmed block (PB), computing an open time associated with the PB and a temperature associated with the PB, the open time representing an amount of time that has elapsed since the PB has initially been programmed with data.

16. The system of claim 15, the operations comprising:
accessing the boundary WL offset table based on the open time and the temperature to retrieve a corresponding set of read level offsets from the boundary WL offset table.

17. The system of claim 15, the operations comprising:
storing a plurality of temperature measurements of the memory device over a time interval;
computing an average of the plurality of temperature measurements; and
using the computed average of the plurality of temperature measurements as the temperature associated with the PB.

18. The system of claim 1, wherein the memory device comprises a three-dimensional (3D) NAND device.

19. At least one non-transitory machine-readable storage medium comprising instructions that, when executed by a processing device, cause the processing device to perform operations comprising:
receiving a request to read data from a portion of a memory device;
in response to receiving the request to read the data, determining whether the portion of the memory device is available for writing data;
retrieving a read offset value based on a temperature associated with the portion of the memory device in response to determining whether the portion of the memory device is available for writing data; and
reading the data from the portion of the memory device based on the retrieved read offset value.

20. A method comprising:
receiving a request to read data from a portion of a memory device;
in response to receiving the request to read the data, determining whether the portion of the memory device is available for writing data;
retrieving a read offset value based on a temperature associated with the portion of the memory device in response to determining whether the portion of the memory device is available for writing data; and
reading the data from the portion of the memory device based on the retrieved read offset value.
